(19) United States
(12) Patent Application Publication
(10) Pub. No.: US 2025/0300429 A1
(43) Pub. Date: Sep. 25, 2025

(54) WAVELENGTH VARIABLE LASER DEVICE AND METHOD FOR CONFIGURING THE SAME

(71) Applicant: NEC Corporation, Tokyo (JP)

(72) Inventor: Kei IYODA, Tokyo (JP)

(73) Assignee: NEC Corporation, Tokyo (JP)

(21) Appl. No.: 19/072,020

(22) Filed: Mar. 6, 2025

(30) Foreign Application Priority Data
Mar. 19, 2024 (JP) 2024-043645

(51) Int. Cl. H01S 5/10

(52) U.S. Cl. CPC H01S 5/1007; H01S 5/101

(57) ABSTRACT

A wavelength variable optical resonator includes a wavelength variable filter and first and second waveguides each including a part inclined relative to a first end surface. A first optical amplifier includes a third waveguide including an active region on which reflection means is provided, the third waveguide being provided between a second end surface and a third end surface opposed to the second end surface and, the third waveguide further including a part inclined relative to the second end surface and extended from the second end surface. A second optical amplifier amplifies a laser light propagating through a fourth waveguide after the laser light whose wavelength is adjusted by the wavelength variable filter is input to the fourth waveguide via a fourth end surface facing the first end surface, the fourth waveguide including a part inclined relative to the fourth end surface and extended from the fourth end surface.

### INCORPORATION BY REFERENCE

This application is based upon and claims the benefit of priority from Japanese patent application No. 2024-43645, filed on Mar. 19, 2024, the disclosure of which is incorporated herein in its entirety by reference.

### TECHNICAL FIELD

The present disclosure relates to a wavelength variable laser device and a method for configuring the same.

### BACKGROUND ART

In optical communications, a wavelength variable laser device capable of adjusting a wavelength of a laser light to be output is used to perform communication using wavelength multiplexing optical signals.

A wavelength variable laser device is configured by connecting a wavelength variable filter chip, which is an external resonator, to a semiconductor optical amplifier. In this case, since an effective refractive index of a waveguide of the wavelength variable filter chip is different from an effective refractive index of a waveguide of the semiconductor optical amplifier, if the waveguides perpendicular to respective end surfaces of the wavelength variable filter chip and the semiconductor optical amplifier are connected together, reflection occurs. As a result, a phenomenon in which laser oscillation becomes unstable occurs. In order to suppress the influence of the reflection, as disclosed in Japanese Unexamined Patent Application Publication No. 2023-108714, it is desired to connect together waveguides tilted relative to the respective end surfaces of the wavelength variable filter chip and the semiconductor optical amplifier by predetermined angles in order to minimize the influence of the reflection.

Further, in the wavelength variable laser device, it is required to achieve stabilization of laser oscillation and control of an optical output independent from each other. As disclosed in Naoki Kobayashi, et al., “Silicon Photonic Hybrid Ring-Filter External Cavity Wavelength Tunable Lasers”, Journal of Lightwave Technology, vol. 33, No. 6, Mar. 15, 2015, pp. 1241-1246 (hereinafter “Non-Patent Literature 1”), two semiconductor optical amplifiers, namely, a semiconductor optical amplifier (SOA) for laser oscillation and a semiconductor optical amplifier (BOA: Booster Optical Amplifier) for optical output, are connected to a wavelength variable filter chip. In this configuration, the SOA, the BOA, and the wavelength variable filter chip are cascade connected in a waveguide direction.

### SUMMARY

In Non-Patent Literature 1, the SOA, the BOA, and the wavelength variable filter chip are cascade connected in the waveguide direction, which causes the dimension of the wavelength variable laser in the waveguide direction to increase. It is therefore difficult to reduce the size of the wavelength variable laser.

In order to solve the above problem, a configuration in which the SOA and the BOA are aligned on one end surface of the wavelength variable filter chip may be employed. However, if the SOA and the BOA are simply aligned on one end surface of the wavelength variable filter chip, the dimension of the wavelength variable filter chip in a direction parallel to the one end surface, which is the direction in which the SOA and the BOA are aligned, becomes large. This causes the reduction in the dimension of the wavelength variable laser device in the direction in which the SOA and the BOA are aligned to be restricted.

A wavelength variable laser device according to one aspect of the present disclosure includes: a wavelength variable optical resonator including a wavelength variable filter capable of adjusting a wavelength of a light to be output, and first and second waveguides each including a part that is inclined relative to a first end surface in such a way that the first and second waveguides are separated from each other from the wavelength variable filter toward the first end surface; a first optical amplifier comprising a third waveguide including an active region, the third waveguide being provided between a second end surface of the first optical amplifier which faces the first end surface and a third end surface of the first optical amplifier which is opposed to the second end surface and on which reflection means is provided, the third waveguide further including a part that is inclined relative to the second end surface and is extended from the second end surface in such a way that the third waveguide and the first waveguide are coaxial with each other; and a second optical amplifier configured to amplify a laser light propagating through a fourth waveguide after the laser light which is oscillated by a resonator provided between the wavelength variable filter and the reflection means and whose wavelength is adjusted to a desired wavelength by the wavelength variable filter is input to the fourth waveguide via a fourth end surface of the second optical amplifier which faces the first end surface, the fourth waveguide including a part that is inclined relative to the fourth end surface and is extended from the fourth end surface in such a way that the fourth waveguide and the second waveguide are coaxial with each other.

A method for forming a wavelength variable laser device according to one aspect of the present disclosure is a method for configuring a wavelength variable laser device, the method including: providing a wavelength variable optical resonator including a wavelength variable filter capable of adjusting a wavelength of a light to be output, and first and second waveguides each including a part that is inclined relative to a first end surface in such a way that the first and second waveguides are separated from each other from the wavelength variable filter toward the first end surface; providing a first optical amplifier comprising a third waveguide including an active region, the third waveguide being provided between a second end surface of the first optical amplifier which faces the first end surface and a third end surface of the first optical amplifier which is opposed to the second end surface and on which reflection means is provided, the third waveguide further including a part that is inclined relative to the second end surface and is extended from the second end surface in such a way that the third waveguide and the first waveguide are coaxial with each other; and providing a second optical amplifier configured to amplify a laser light propagating through a fourth waveguide after the laser light which is oscillated by a resonator provided between the wavelength variable filter and the reflection means and whose wavelength is adjusted to a desired wavelength by the wavelength variable filter is input to the fourth waveguide via a fourth end surface of the second optical amplifier which faces the first end surface, the fourth waveguide including a part that is inclined relative to the fourth end surface and is extended from the fourth end surface in such a way that the fourth waveguide and the second waveguide are coaxial with each other.

According to the present disclosure, it is possible to reduce a size of a wavelength variable laser device with a simple configuration.

### BRIEF DESCRIPTION OF DRAWINGS

The above and other aspects, features and advantages of the present disclosure will become more apparent from the following description of certain exemplary embodiments when taken in conjunction with the accompanying drawings, in which:

FIG. 1 is a diagram schematically showing a configuration of a wavelength variable laser device according to one example embodiment;

FIG. 2 is a diagram schematically showing a configuration of a general wavelength variable laser device;

FIG. 3 is a diagram showing a first example of reduction in a size of the wavelength variable laser device; and

FIG. 4 is a diagram showing a second example of the reduction in the size of the wavelength variable laser device.

### EXAMPLE EMBODIMENT

Hereinafter, with reference to the drawings, example embodiments of the present disclosure will be described. Throughout the drawings, the same components are denoted by the same reference symbols and redundant descriptions will be omitted as necessary.

### First Example Embodiment

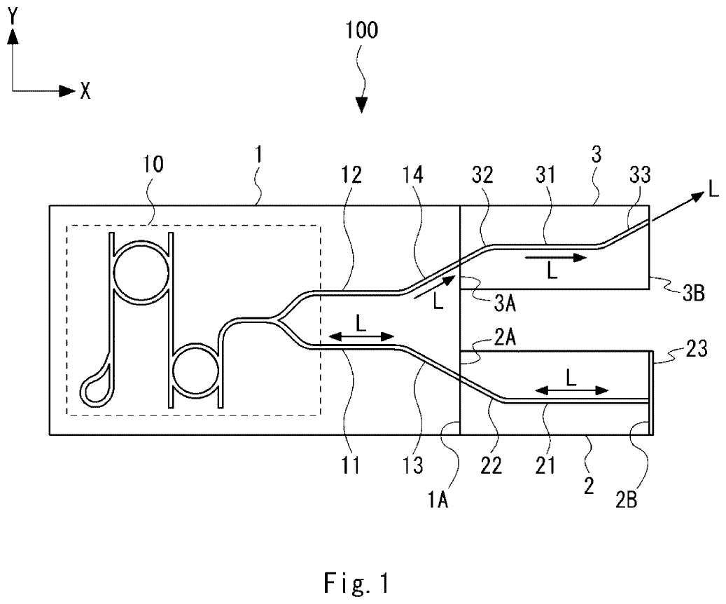

A wavelength variable laser device according to a first example embodiment will be described. FIG. 1 is a diagram schematically showing a configuration of a wavelength variable laser device according to one example embodiment. A wavelength variable laser device 100 includes a wavelength variable optical resonator 1 and two semiconductor optical amplifiers. In this configuration, the two semiconductor optical amplifiers are a semiconductor optical amplifier (SOA) 2 for laser oscillation and a semiconductor amplifier (BOA: Booster Optical Amplifier) 3 for optical output. The wavelength variable optical resonator 1, the SOA 2, and the BOA 3 are mounted, for example, on a substrate that is not shown.

Hereinafter, a horizontal direction from the left to the right of the drawings, which is a lengthwise direction of the wavelength variable laser device, is defined as an X direction. A vertical direction from the bottom to the top of the drawings, which is a short direction of the wavelength variable laser device, is defined as a Y direction. In this example, +Y direction is also referred to as a first direction and −Y direction is also referred to as a second direction.

An end surface of the wavelength variable optical resonator 1 in the +X direction on which the light is made incident or from which the light is emitted is referred to as an end surface 1A. The SOA 2 and the BOA 3 are aligned in the Y direction, which is the direction parallel to the end surface 1A, near the end surface 1A of the wavelength variable optical resonator 1. In the following description, each of the end surfaces of the wavelength variable optical resonator 1, the SOA 2, and the BOA 3 is a surface perpendicular to its lengthwise direction; that is, the X direction.

In this configuration, it is desired that the SOA 2 and the BOA 3 be disposed in such a way that they are separated from each other with a predetermined distance therebetween. This is effective to avoid the following influence at the time of mounting. In a case where, for example, the BOA 3 is mounted after the SOA 2 is mounted, if the place where the SOA 2 is mounted and the place where the BOA 3 is mounted are close to each other, it is possible that the BOA 3 may contact the SOA 2 or a tool that is used to mount the BOA 3 may contact the SOA 2. This may cause an axial displacement in one or both of the SOA 2 and the BOA 3, resulting in an unstable laser oscillation. In order to avoid this problem that may occur in the mounting process, it is desired that the SOA 2 and the BOA 3 be separated by a distance sufficient to prevent physical interference between them while they are mounted.

Further, by causing the SOA 2 to be separated from the BOA 3, the influence of the heat emitted by one of the SOA 2 or the BOA 3 on the other one of the SOA 2 or the BOA 3 can be prevented or suppressed.

The wavelength variable optical resonator 1 includes a wavelength variable filter 10, straight waveguides 11 and 12, and inclined waveguides 13 and 14. The straight waveguide 11 and the inclined waveguide 13 form a path that connects the wavelength variable filter 10 to the SOA 2. The straight waveguide 12 and the inclined waveguide 14 form a path that connects the wavelength variable filter 10 to the BOA 3.

In this example, the straight waveguide 11 and the inclined waveguide 13 are also referred to as a first waveguide. The straight waveguide 11 is also referred to as a seventh part included in the first waveguide. The inclined waveguide 13 is also referred to as a sixth part included in the first waveguide. The straight waveguide 12 and the inclined waveguide 14 are also referred to as a second waveguide. The straight waveguide 12 is also referred to as a ninth part included in the second waveguide. The inclined waveguide 14 is also referred to as an eighth part included in the second waveguide. The end surface 1A is also referred to as a first end surface.

The wavelength variable filter 10 includes, for example, one or more ring waveguide, where the wavelength of a light propagating through this waveguide can be adjusted. FIG. 1 shows an example in which the wavelength variable filter 10 includes two ring waveguides. However, this wavelength variable filter 10 is merely one example, and another configuration may be employed as appropriate. Just like a general wavelength variable filter formed of a ring waveguide(s), the wavelength variable filter 10 can adjust the wavelength of the light reciprocating in a resonator provided between the wavelength variable filter 10 and a reflection member provided on an end surface of the SOA 2 to a desired wavelength. Then, the wavelength variable filter 10 outputs a laser light L having a desired wavelength to the BOA 3 through the straight waveguide 12 and the inclined waveguide 14.

The straight waveguide 11 and the inclined waveguide 13 are connected optically smoothly in a cascade manner in the lengthwise direction of the wavelength variable optical resonator 1. The straight waveguide 11, which is extended from the wavelength variable filter 10 in the lengthwise direction of the wavelength variable optical resonator 1, is connected to the inclined waveguide 13. The inclined waveguide 13 is extended from a connection part thereof to the straight waveguide 11 toward the end surface 1A which faces the SOA 2 in such a way that the inclined waveguide 13 has a predetermined angle relative to the end surface 1A. Accordingly, it is possible to suppress the reflection of the light that is emitted from the inclined waveguide 13 via the end surface 1A and the light that is made incident on the inclined waveguide 13 via the end surface 1A on the end surface 1A. It is desired that the angle of the inclined waveguide 13 relative to the end surface 1A be determined in such a way that the reflection of the light on the end surface 1A is minimized or kept within a desired range.

The straight waveguide 12 and the inclined waveguide 14 are cascade connected optically smoothly in the lengthwise direction of the wavelength variable optical resonator 1. The straight waveguide 12, which is extended in the lengthwise direction of the wavelength variable optical resonator 1 from the wavelength variable filter 10, is connected to the inclined waveguide 14. The inclined waveguide 14 is extended from a connection part thereof to the straight waveguide 12 toward the end surface 1A in such a way that the inclined waveguide 14 has a predetermined angle relative to the end surface 1A. Note that the inclined waveguide 14 is provided so as to be inclined in a direction opposite to that of the inclined waveguide 13. In other words, the inclined waveguides 13 and 14 are provided in such a way that they are separated away from each other toward the end surface 1A. Accordingly, it is possible to suppress the reflection of the light emitted from the inclined waveguide 14 via the end surface 1A on the end surface 1A. It is desired that the angle of the inclined waveguide 14 relative to the end surface 1A be determined in such a way that the reflection of the light on the end surface 1A is minimized or kept within a desired range.

Note that it is desirable that the inclined waveguide 13 and the inclined waveguide 14 be inclined in directions opposite to each other with the axis that is along the X direction therebetween. Further, the inclined waveguide 13 and the inclined waveguide 14 may be disposed in such a way that they are symmetrical to each other relative to an axis along the X direction. That is, the inclination angle of the inclined waveguide 13 in the clockwise direction relative to the end surface 1A may be the same as the inclination angle of the inclined waveguide 14 in the counterclockwise direction relative to the end surface 1A.

The SOA 2 is configured as a light emitting device where an active region is provided. The SOA 2 is configured, for example, as a semiconductor optical amplifier.

The SOA 2 is provided with a straight waveguide 21 and an inclined waveguide 22 cascade connected optically smoothly in its lengthwise direction. The active region is provided in one or both of the straight waveguide 21 and the inclined waveguide 22, or is provided to be close to the straight waveguide 21 and the inclined waveguide 22. The inclined waveguide 22 and the straight waveguide 21 are provided in this order between an end surface 2A of the SOA 2 which faces the end surface 1A and an end surface 2B of the SOA 2 that is opposed to the end surface 2A. A member that reflects the light that is made incident from the end surface 2B, for example, a total reflection mirror 23, is formed on the end surface 2B. The total reflection mirror 23 may be, for example, a mirror that is composed of multi-layer films.

In this example, the SOA 2 is also referred to as a first optical amplifier. The straight waveguide 21 and the inclined waveguide 22 are also referred to as a third waveguide. The inclined waveguide 22 is also referred to as a first part included in the third waveguide. The straight waveguide 21 is also referred to as a second part included in the third waveguide. The end surfaces 2A and 2B are also referred to as second and third end surfaces, respectively.

The inclined waveguide 22 is extended from a connection part thereof to the straight waveguide 21 extended in the lengthwise direction of the SOA 2 toward the end surface 2A in such a way that the inclined waveguide 22 has a predetermined angle relative to the end surface 2A. The inclined waveguide 22 is inclined so as to be extended in a direction the same as that of the inclined waveguide 13 of the wavelength variable optical resonator 1. The SOA 2 is disposed in such a way that the inclined waveguide 22 and the inclined waveguide 13 are coaxial with each other. Accordingly, the reflection of the light emitted from the inclined waveguide 22 via the end surface 2A and the light that is made incident on the inclined waveguide 22 via the end surface 2A on the end surface 2A can be suppressed. It is desired that the angle of the inclined waveguide 22 relative to the end surface 2A be determined in such a way that the reflection of the light on the end surface 2A is minimized or kept within a desired range.

The BOA 3 is configured as an optical amplifier that amplifies a laser light that is made incident on the provided optical waveguide. The BOA 3 is configured, for example, as a semiconductor optical amplifier.

The BOA 3 includes a straight waveguide 31 and inclined waveguides 32 and 33 that are cascade connected in the lengthwise direction of the BOA 3. The inclined waveguide 32, the straight waveguide 31, and the inclined waveguide 33 are connected in this order from an end surface 3A of the BOA 3 which faces the end surface 1A toward an end surface 3B of the BOA 3, which is an emission surface of the light.

In this example, the BOA 3 is also referred to as a second optical amplifier. The straight waveguide 31 and the inclined waveguides 32 and 33 are also referred to as a fourth waveguide. The inclined waveguide 32 is also referred to as a third part included in the fourth waveguide. The straight waveguide 31 is also referred to as a fourth part included in the fourth waveguide. The inclined waveguide 33 is also referred to as a fifth part included in the fourth waveguide. The end surfaces 3A and 3B are also referred to as fourth and fifth end surfaces, respectively.

The inclined waveguide 32 is extended from a connection part thereof with the straight waveguide 31 extended in the lengthwise direction of the BOA 3 toward the end surface 3A in such a way that the inclined waveguide 32 has a predetermined angle relative to the end surface 3A. The inclined waveguide 32 is inclined so as to be extended in a direction the same as that of the inclined waveguide 14 of the wavelength variable optical resonator 1. The BOA 3 is disposed in such a way that the inclined waveguide 32 and the inclined waveguide 14 are coaxial with each other. Accordingly, the reflection of the light that is made incident on the inclined waveguide 32 via the end surface 3A on the end surface 3A can be suppressed. It is desirable that the angle of the inclined waveguide 32 relative to the end surface 3A be determined in such a way that the reflection of the light on the end surface 3A is minimized or kept within a desired range.

The inclined waveguide 33 is extended from a connection part thereof with the straight waveguide 31 toward the end surface 3B in such a way that the inclined waveguide 33 has a predetermined angle relative to the end surface 3B. Accordingly, the reflection of the light emitted from the inclined waveguide 33 via the end surface 3B on the end surface 3B can be suppressed. It is desired that the angle of the inclined waveguide 33 relative to the end surface 3B be determined in such a way that the reflection of the light on the end surface 3B is minimized or kept within a desired range. The inclined waveguide 33 may be inclined so as to be extended in a direction the same as that of the inclined waveguide 32.

Next, a light propagation path will be described. In this configuration, the SOA 2 performs laser oscillation as a light that has occurred by injecting electrical current into the active region provided in the straight waveguide 21 reciprocates between the total reflection mirror 23 provided on the end surface 2B of the SOA 2 and the wavelength variable filter 10. In FIG. 1, the oscillated laser light is shown by a symbol L, and its propagation directions are shown by arrows. As described above, the oscillation wavelength of the laser light L can be adjusted to a desired wavelength by the wavelength variable filter 10.

The laser light L having a desired wavelength is emitted to the BOA 3 from the wavelength variable filter 10 via the straight waveguide 12 and the inclined waveguide 14. The laser light L that is made incident on the BOA 3 is amplified to a desired intensity as it propagates through the straight waveguide 31, the inclined waveguide 32, and the inclined waveguide 33, and then emitted from the end surface 3B, which is an emission surface.

According to this configuration described above, even in a case where the SOA 2 and the BOA 3 are arranged in such a manner that they are separated from each other by a predetermined distance in the Y direction in order to avoid the problem that may occur when the SOA 2 and the BOA 3 are mounted, the dimension of the wavelength variable laser device 100 in the Y direction can be reduced. Therefore, according to this configuration, it is possible to reduce the size of the wavelength variable laser device.

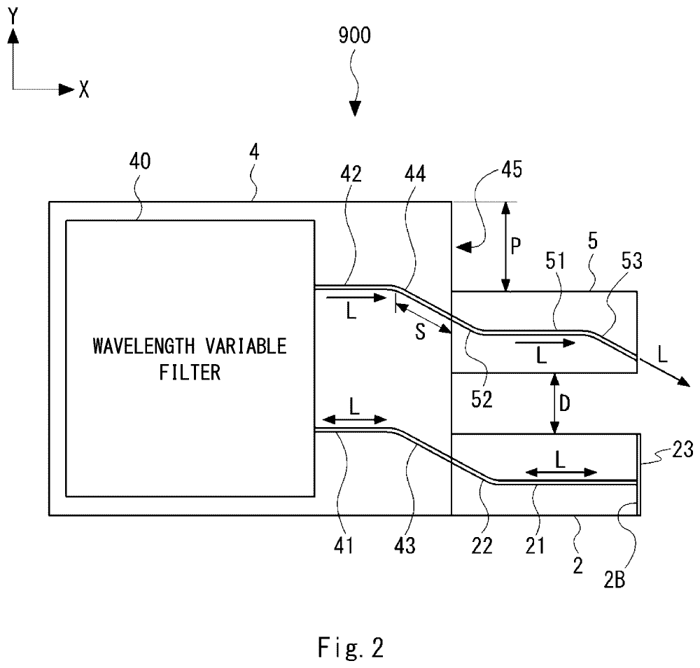

Next, advantages of the wavelength variable laser device 100 in terms of reducing the size of the wavelength variable laser device as compared to a general wavelength variable laser device 900 will be described. FIG. 2 is a diagram schematically showing a configuration of the general wavelength variable laser device. A general wavelength variable laser device 900 has a configuration in which the wavelength variable optical resonator 1 and the BOA 3 of the wavelength variable laser device 100 according to the first example embodiment are replaced by a wavelength variable optical resonator 4 and a BOA 5, respectively.

A wavelength variable filter 40, straight waveguides 41 and 42, and inclined waveguides 43 and 44 of the wavelength variable optical resonator 4 respectively correspond to the wavelength variable filter 10, the straight waveguides 11 and 12, and the inclined waveguides 13 and 14 of the wavelength variable optical resonator 1. However, the inclined waveguide 44 is inclined in a direction opposite to that of the inclined waveguide 14.

Straight waveguide 51 and inclined waveguides 52 and 53 of the BOA 5 respectively correspond to the straight waveguide 31 and the inclined waveguides 32 and 33 of the BOA 3. However, the straight waveguide 51 and the inclined waveguides 52 and 53 are respectively inverted relative to the straight waveguide 31 and the inclined waveguides 32 and 33 along the Y direction; that is, disposed in such a way that they are symmetrical to each other with an axis along the X direction.

As described above, in the wavelength variable laser device 100, the inclined waveguide 22 of the SOA 2 and the inclined waveguide 32 of the BOA 3 are inclined in the opposite directions, whereas in the general wavelength variable laser device 900, an inclined waveguide 22 of an SOA 2 and the inclined waveguide 52 of the BOA 5 are inclined in the same direction. Therefore, if the distance between the SOA 2 and the BOA 5 is maintained to be a distance D, which is the same as the distance between the SOA 2 and the BOA 3, in the general wavelength variable laser device 900, the positions of the straight waveguide 42 and the inclined waveguide 44 of the wavelength variable optical resonator 4 are shifted in the +Y direction as compared to the positions of the straight waveguide 12 and the inclined waveguide 14 of the wavelength variable optical resonator 1. As a result, as shown by a symbol 45 in FIG. 2, an end part of the wavelength variable optical resonator 4 in the +Y direction is protruded in the +Y direction as compared to the BOA 5.

Therefore, the dimension of the wavelength variable optical resonator 4 in the Y direction becomes greater than the dimension of the wavelength variable optical resonator 1 in the Y direction. As a result, the general wavelength variable laser device 900 is disadvantageous compared to the wavelength variable laser device 100 as the former cannot enable the size of the wavelength variable laser device to be reduced as much as the latter can.

On the other hand, with the wavelength variable laser device 100 according to this example embodiment, even in a case where the SOA 2 and the BOA 3 are disposed at predetermined intervals in the Y direction, the dimension of the wavelength variable laser device 100 in the Y direction can be reduced compared to that in the general wavelength variable laser device 900. That is, with the wavelength variable laser device 100, it becomes possible to further reduce the size of the wavelength variable laser device.

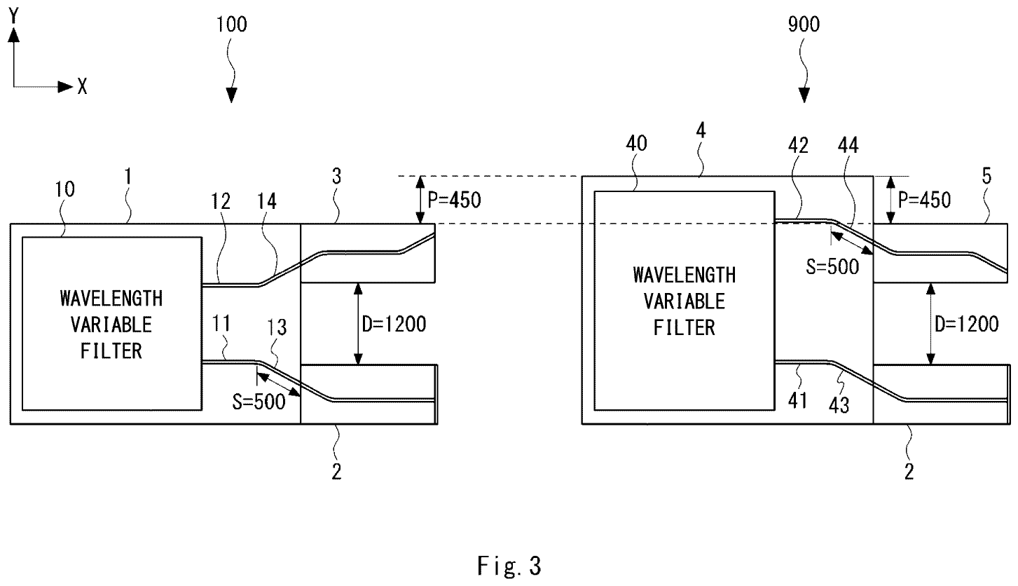

Hereinafter, specific examples of the effect of reducing the size of the wavelength variable laser device 100 will be described. FIG. 3 is a diagram showing a first example of the reduction in the size of the wavelength variable laser device. In this example, a dimension S of the inclined waveguides 13 and 14 of the wavelength variable laser device 100 and a dimension S of the inclined waveguides 43 and 44 of the general wavelength variable laser device 900 are 500 μm. A distance D between the SOA 2 and the BOA 3 and a distance D between the SOA 2 and the BOA 5 are 1200 μm.

In this example, the position of the end part of the wavelength variable optical resonator 4 in the +Y direction is protruded in the +Y direction as compared to the position of the end part of the wavelength variable optical resonator 1 in the +Y direction by an amount of shift P of about 450 μm. It is therefore appreciated that the wavelength variable laser device 100 can reduce the dimension thereof in the Y direction by about 450 μm compared to that of the general wavelength variable laser device 900.

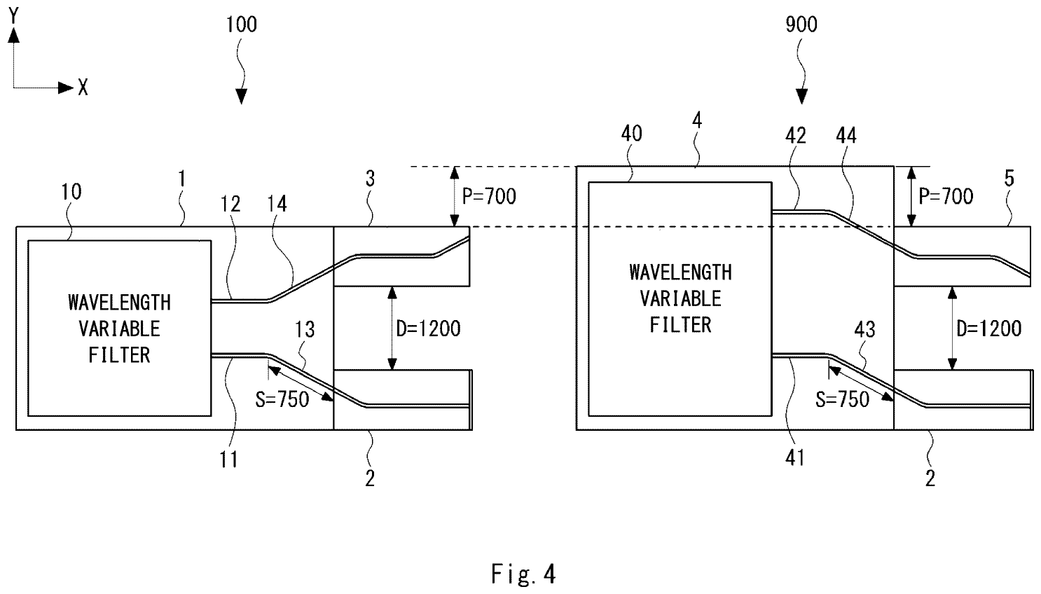

FIG. 4 is a diagram showing a second example of the reduction in the size of the wavelength variable laser device. In this example, the dimension S of the inclined waveguides 13 and 14 of the wavelength variable laser device 100 and the dimension S of the inclined waveguides 43 and 44 of the general wavelength variable laser device 900 are 750 μm. The distance D between the SOA 2 and the BOA 3 and the distance D between the SOA 2 and the BOA 5 are 1200 μm.

In this example, the position of the end part of the wavelength variable optical resonator 4 in the +Y direction is protruded in the +Y direction as compared to the position of the end part of the wavelength variable optical resonator 1 in the +Y direction by an amount of shift P of about 700 ρm. It is therefore appreciated that the wavelength variable laser device 100 can reduce the dimension thereof in the Y direction by about 700 μm compared to that of the general wavelength variable laser device 900.

As described above, according to this configuration, it is possible to further reduce the size of the wavelength variable laser device as compared to the general wavelength variable laser device.

### Other Example Embodiments

While the present disclosure has been described with reference to the example embodiments, the present disclosure is not limited to the aforementioned example embodiments. Various changes that may be understood by those skilled in the art within the scope of the present disclosure can be made to the configurations and the details of the present disclosure. Then, each of the example embodiments may be combined with other example embodiments as appropriate.

For example, the waveguides formed in the wavelength variable optical resonator 1, the SOA 2, and the BOA 3 may have the same width or may include parts having different widths as required. For example, in each of waveguides provided near the end surfaces of the wavelength variable optical resonator 1, the SOA 2 and the BOA 3, a spot-size converter or the like in which the width becomes narrower toward the end surfaces may be provided as appropriate.

The wavelength variable optical resonator 1, the SOA 2, and the BOA 3 may be configured as various kinds of semiconductor devices of any material; for example, silicon-based or indium phosphorus-based semiconductor devices. Further, the wavelength variable optical resonator 1, the SOA 2, and the BOA 3 may be manufactured by various kinds of semiconductor processes.

Each of the drawings is merely an example for describing one or more example embodiments. Each of the drawings is not associated with only one particular example embodiment and may instead be associated with one or more other example embodiments. Those skilled in the art will appreciate that various features or steps described with reference to any one of the drawings may be combined with features or steps shown in one or more other drawings in order to produce, for example, example embodiments that are not explicitly illustrated or described. Not all the features or steps shown in any one of the figures to describe illustrative example embodiments are necessary, and some of the features or steps may be omitted. The order of the steps shown in any one of the figures may be changed as appropriate.

The whole or part of the example embodiments disclosed above can be described as, but not limited to, the following supplementary notes.

### Supplementary Note 1

A wavelength variable laser device comprising:
a wavelength variable optical resonator including a wavelength variable filter capable of adjusting a wavelength of a light to be output, and first and second waveguides each including a part that is inclined relative to a first end surface in such a way that the first and second waveguides are separated from each other from the wavelength variable filter toward the first end surface;
a first optical amplifier comprising a third waveguide including an active region, the third waveguide being provided between a second end surface of the first optical amplifier which faces the first end surface and a third end surface of the first optical amplifier which is opposed to the second end surface and on which reflection means is provided, the third waveguide further including a part that is inclined relative to the second end surface and is extended from the second end surface in such a way that the third waveguide and the first waveguide are coaxial with each other; and
a second optical amplifier configured to amplify a laser light propagating through a fourth waveguide after the laser light which is oscillated by a resonator provided between the wavelength variable filter and the reflection means and whose wavelength is adjusted to a desired wavelength by the wavelength variable filter is input to the fourth waveguide via a fourth end surface of the second optical amplifier which faces the first end surface, the fourth waveguide including a part that is inclined relative to the fourth end surface and is extended from the fourth end surface in such a way that the fourth waveguide and the second waveguide are coaxial with each other.

### Supplementary Note 2

The wavelength variable laser device according to Supplementary Note 1, wherein
the first waveguide is inclined in a first direction that is parallel to the end surface relative to the first end surface, and
the second waveguide is inclined in a second direction, which is opposite to the first direction.

### Supplementary Note 3

The wavelength variable laser device according to Supplementary Note 2, wherein the first waveguide and the second waveguide are disposed in such a way that they are symmetrical to each other with an axis perpendicular to the first end surface therebetween.

### Supplementary Note 4

The wavelength variable laser device according to any one of Supplementary Notes 1 to 3, wherein the part of the third waveguide inclined relative to the second end surface and the part of the fourth waveguide inclined relative to the fourth end surface are disposed in such a way that they are symmetrical to each other with an axis perpendicular to the first end surface therebetween.

### Supplementary Note 5

The wavelength variable laser device according to any one of Supplementary Notes 1 to 4, wherein the third waveguide comprises a first part inclined relative to the second end surface and a second part that is extended in a direction perpendicular to the third end surface between the first part and the third end surface.

### Supplementary Note 6

The wavelength variable laser device according to any one of Supplementary Notes 1 to 5, wherein
the fourth waveguide comprises:
   a third part inclined relative to the fourth end surface;
   a fourth part that is extended from the third part in a direction perpendicular to the fourth end surface; and
   a fifth part that is extended to be inclined relative to a fifth end surface that is opposed to the fourth end surface from the fourth part toward the fifth end surface, and
the laser light is emitted from the fifth part via the fifth end surface.

### Supplementary Note 7

The wavelength variable laser device according to Supplementary Note 6, wherein the third part and the fifth part are inclined in the same direction relative to the fourth end surface and the fifth end surface.

### Supplementary Note 8

The wavelength variable laser device according to any one of Supplementary Notes 1 to 7, wherein
the first waveguide comprises a sixth part inclined relative to the first end surface and a seventh part that is extended in a direction perpendicular to the first end surface between the sixth part and the wavelength variable filter, and
the second waveguide comprises an eighth part inclined relative to the first end surface and a ninth part that is extended in a direction perpendicular to the first end surface between the eighth part and the wavelength variable filter.

### Supplementary Note 9

The wavelength variable laser device according to any one of Supplementary Notes 1 to 8, wherein the reflection means is a total reflection mirror that reflects a light incident from the third waveguide.

### Supplementary Note 10

A method for forming a wavelength variable laser device comprising, the method comprising:
providing a wavelength variable optical resonator including a wavelength variable filter capable of adjusting a wavelength of a light to be output, and first and second waveguides each including a part that is inclined relative to a first end surface in such a way that the first and second waveguides are separated from each other from the wavelength variable filter toward the first end surface;
providing a first optical amplifier comprising a third waveguide including an active region, the third waveguide being provided between a second end surface of the first optical amplifier which faces the first end surface and a third end surface of the first optical amplifier which is opposed to the second end surface and on which reflection means is provided, the third waveguide further including a part that is inclined relative to the second end surface and is extended from the second end surface in such a way that the third waveguide and the first waveguide are coaxial with each other; and
providing a second optical amplifier configured to amplify a laser light propagating through a fourth waveguide after the laser light which is oscillated by a resonator provided between the wavelength variable filter and the reflection means and whose wavelength is adjusted to a desired wavelength by the wavelength variable filter is input to the fourth waveguide via a fourth end surface of the second optical amplifier which faces the first end surface, the fourth waveguide including a part that is inclined relative to the fourth end surface and is extended from the fourth end surface in such a way that the fourth waveguide and the second waveguide are coaxial with each other.

What is claimed is:

1. A wavelength variable laser device comprising:
a wavelength variable optical resonator including a wavelength variable filter capable of adjusting a wavelength of a light to be output, and first and second waveguides each including a part that is inclined relative to a first end surface in such a way that the first and second waveguides are separated from each other from the wavelength variable filter toward the first end surface;
a first optical amplifier comprising a third waveguide including an active region, the third waveguide being provided between a second end surface of the first optical amplifier which faces the first end surface and a third end surface of the first optical amplifier which is opposed to the second end surface and on which a reflector is provided, the third waveguide further including a part that is inclined relative to the second end surface and is extended from the second end surface in such a way that the third waveguide and the first waveguide are coaxial with each other; and
a second optical amplifier configured to amplify a laser light propagating through a fourth waveguide after the laser light which is oscillated by a resonator provided between the wavelength variable filter and the reflector and whose wavelength is adjusted to a desired wavelength by the wavelength variable filter is input to the fourth waveguide via a fourth end surface of the second optical amplifier which faces the first end surface, the fourth waveguide including a part that is inclined relative to the fourth end surface and is extended from the fourth end surface in such a way that the fourth waveguide and the second waveguide are coaxial with each other.

2. The wavelength variable laser device according to claim 1, wherein
the first waveguide is inclined in a first direction that is parallel to the end surface relative to the first end surface, and
the second waveguide is inclined in a second direction, which is opposite to the first direction.

3. The wavelength variable laser device according to claim 2, wherein the first waveguide and the second waveguide are disposed in such a way that they are symmetrical to each other with an axis perpendicular to the first end surface therebetween.

4. The wavelength variable laser device according to claim 1, wherein the part of the third waveguide inclined relative to the second end surface and the part of the fourth waveguide inclined relative to the fourth end surface are disposed in such a way that they are symmetrical to each other with an axis perpendicular to the first end surface therebetween.

5. The wavelength variable laser device according to claim 1, wherein the third waveguide comprises a first part inclined relative to the second end surface and a second part that is extended in a direction perpendicular to the third end surface between the first part and the third end surface.

6. The wavelength variable laser device according to claim 1, wherein
the fourth waveguide comprises:
a third part inclined relative to the fourth end surface;
a fourth part that is extended from the third part in a direction perpendicular to the fourth end surface; and
a fifth part that is extended to be inclined relative to a fifth end surface that is opposed to the fourth end surface from the fourth part toward the fifth end surface, and
the laser light is emitted from the fifth part via the fifth end surface.

7. The wavelength variable laser device according to claim 6, wherein the third part and the fifth part are inclined in the same direction relative to the fourth end surface and the fifth end surface.

8. The wavelength variable laser device according to claim 1, wherein
the first waveguide comprises a sixth part inclined relative to the first end surface and a seventh part that is extended in a direction perpendicular to the first end surface between the sixth part and the wavelength variable filter, and
the second waveguide comprises an eighth part inclined relative to the first end surface and a ninth part that is extended in a direction perpendicular to the first end surface between the eighth part and the wavelength variable filter.

9. The wavelength variable laser device according to claim 1, wherein the reflector is a total reflection mirror that reflects a light incident from the third waveguide.

10. A method for configuring a wavelength variable laser device, the method comprising:
providing a wavelength variable optical resonator including a wavelength variable filter capable of adjusting a wavelength of a light to be output, and first and second waveguides each including a part that is inclined relative to a first end surface in such a way that the first and second waveguides are separated from each other from the wavelength variable filter toward the first end surface;
providing a first optical amplifier comprising a third waveguide including an active region, the third waveguide being provided between a second end surface of the first optical amplifier which faces the first end surface and a third end surface of the first optical amplifier which is opposed to the second end surface and on which a reflector is provided, the third waveguide further including a part that is inclined relative to the second end surface and is extended from the second end surface in such a way that the third waveguide and the first waveguide are coaxial with each other; and
providing a second optical amplifier configured to amplify a laser light propagating through a fourth waveguide after the laser light which is oscillated by a resonator provided between the wavelength variable filter and the reflector and whose wavelength is adjusted to a desired wavelength by the wavelength variable filter is input to the fourth waveguide via a fourth end surface of the second optical amplifier which faces the first end surface, the fourth waveguide including a part that is inclined relative to the fourth end surface and is extended from the fourth end surface in such a way that the fourth waveguide and the second waveguide are coaxial with each other.
